(19) United States
(12) Patent Application Publication
(10) Pub. No.: US 2016/0064301 A1
(43) Pub. Date: Mar. 3, 2016

(54) SEMICONDUCTOR DEVICE

(71) Applicants: Atsushi TOMOHIRO, Tokyo (JP); PS4 LUXCO S.A.R.L., Luxembourg (LU)

(72) Inventor: Atsushi Tomohiro, Tokyo (JP)

(73) Assignee: PS4 Luxco S.a.r.l., Luxembourg (LU)

(21) Appl. No.: 14/784,632

(22) PCT Filed: Apr. 11, 2014
(86) PCT No.: PCT/JP2014/060466

§ 371 Date: Oct. 15, 2015

(30) Foreign Application Priority Data
Apr. 17, 2013 (JP) 2013-086447

(51) Int. Cl. H01L 23/367; H01L 23/31; H05K 1/18; H05K 1/11; H01L 25/10; H01L 23/498; H05K 1/02

(52) U.S. Cl. CPC H01L 23/3675; H01L 23/49838; H01L 23/3107; H05K 1/0206; H05K 1/111; H01L 23/49816; H01L 25/105; H05K 1/181; H01L 2225/1023; H01L 2225/1058; H01L 2225/1094

(57) ABSTRACT

One semiconductor device includes a wiring board, a semiconductor chip, and an encapsulation body. The wiring board includes an insulating base, a conductive pattern that is formed on one surface of the insulating base, and a heat dissipation via that is connected to the conductive pattern. The heat dissipation via is provided so as to penetrate through the insulating base from one surface to the other surface, while being exposed from the lateral side of the insulating base. The semiconductor chip is mounted on the wiring board so as to overlap the conductive pattern. The encapsulation body is formed on the wiring board so as to cover the semiconductor chip.

### TECHNICAL FIELD

The present invention relates to a semiconductor device comprising semiconductor chips.

### BACKGROUND

Progress has been made in recent years in increasing the speed of semiconductor devices having semiconductor chips such as memory chips and logic chips, so the rate of operation etc. of semiconductor chips has increased, making the semiconductor chips more likely to generate heat. It is therefore necessary to release the heat of the semiconductor chips to outside of the semiconductor device. A large number of organic members which do not readily transfer heat are used in ball grid array (BGA) semiconductor devices in particular, so heat is not readily released into the air from the semiconductor chips in the semiconductor device.

In the semiconductor device described in Patent Document 1, a package is mounted on a mounting board, the package comprising a wiring board and a sealing material, and the wiring board holds a semiconductor chip (semiconductor element). In the semiconductor device, a plurality of heat-radiating solder balls (solder bumps) are provided in a central region of a connecting surface (board connection surface) of the package wiring board with the mounting board. The semiconductor device described in Patent Document 1 has a structure in which heat is transferred from the semiconductor chip to the plurality of heat-radiating solder balls, so heat generated by the semiconductor chip is transferred to the mounting board connected to the semiconductor chip by way of the heat-radiating solder balls, and the heat is released from the mounting board to outside of the semiconductor device.

### Patent Document

Patent Document 1: JP 2000-68403 A

### SUMMARY OF THE INVENTION

### Problem to be Solved by the Invention

With the invention described in Patent Document 1, however, the heat-radiating solder balls have to be separately provided in the semiconductor device, and therefore the cost of manufacturing the semiconductor device as a whole increases.

A description will now be given of using the package described in Patent Document 1 for a Package-on-Package (PoP) arrangement in which a plurality of packages having different types of semiconductor chips are stacked. In a PoP semiconductor device, the semiconductor chip of a package positioned below is located directly under the central region of a package stacked on top, so there is no space to provide a plurality of heat-radiating solder balls in the central region of the connecting surface of the package stacked on top. If the heat-radiating solder balls are arranged with a gap being provided between the package on top and the package below, the semiconductor chip of the package below comes into contact with the heat-radiating solder balls and there is no longer contact between the heat-radiating solder balls and the mounting board. As a result, the heat generated by the semiconductor chip cannot be transferred to the mounting board through the heat-radiating solder balls and released, and this leads to a problem in that heat is retained by the semiconductor device.

### Means for Solving the Problem

In order to achieve the abovementioned aim, a semiconductor device according to the present invention comprises a wiring board, a semiconductor chip, and a sealing material. The wiring board includes an insulating substrate, a conductive pattern formed on a first surface of the insulating substrate, and heat-radiating vias which are connected to the conductive pattern. The heat-radiating vias are provided in such a way as to be exposed at the sides of the insulating substrate while also passing through the insulating substrate from the first surface to a second surface thereof. The semiconductor chip is mounted on the wiring board in such a way as to lie over the conductive pattern. The sealing material is formed on the wiring board in such a way as to cover the semiconductor chip.

### Advantage of the Invention

According to the present invention, a conductive pattern is formed on a first surface of an insulating substrate, so heat generated by a semiconductor chip mounted in such a way as to lie over the conductive pattern is transmitted to the conductive pattern. The heat transmitted to the conductive pattern is then transmitted to the heat-radiating vias which are connected to the conductive pattern, are exposed at the sides of the insulating substrate, and pass through the insulating substrate from the first surface to a second surface thereof, and the heat is then released to outside of the semiconductor device from the heat-radiating vias. This means that it is unnecessary to form a plurality of heat-radiating solder balls in the central region of a semiconductor chip wiring board, and this keeps down the cost of manufacturing the semiconductor device as a whole. Furthermore, a package comprising the semiconductor device according to the present invention can also be used in a PoP semiconductor device because there is no need to form the heat-radiating solder balls.

Furthermore, the heat generated by the semiconductor chip is released to the outside from the heat-radiating vias which are exposed at the sides of the insulating substrate, and as a result there is less risk of heat generated by the semiconductor chip being retained by the semiconductor device, and the reliability of the semiconductor device can be improved.

### BRIEF DESCRIPTION OF THE FIGURES

FIG. 1 is a plan view showing a semiconductor device according to a first mode of embodiment of the present invention;

FIG. 2a is a view in the cross section A-A′ in FIG. 1;

FIG. 2b is a view in the cross section B-B′ in FIG. 1;

FIG. 3a is a view in cross section showing a step in the assembly of the semiconductor device according to the first mode of embodiment;

FIG. 3b is a view in cross section showing a step in the assembly of the semiconductor device according to the first mode of embodiment;

FIG. 3c is a view in cross section showing a step in the assembly of the semiconductor device according to the first mode of embodiment;

FIG. 3d is a view in cross section showing a step in the assembly of the semiconductor device according to the first mode of embodiment;

FIG. 3e is a view in cross section showing a step in the assembly of the semiconductor device according to the first mode of embodiment;

FIG. 4 is a view in cross section showing a PoP semiconductor device according to the first mode of embodiment;

FIG. 5 is a view in cross section showing the situation when the semiconductor device according to the first mode of embodiment is mounted on a mounting board inside an electronic device;

FIG. 6 is a plan view showing a semiconductor device according to a second mode of embodiment of the present invention;

FIG. 7 is a view in cross section showing a semiconductor device according to a third mode of embodiment of the present invention;

FIG. 8 is a plan view showing a semiconductor device according to a fourth mode of embodiment of the present invention;

FIG. 9 is a plan view showing a semiconductor device according to a fifth mode of embodiment of the present invention; and

FIG. 10 is a plan view showing a semiconductor device according to a sixth mode of embodiment of the present invention.

### MODE OF EMBODIMENT OF THE INVENTION

Modes of embodiment of the present invention will be described below with reference to the figures.

### First Mode of Embodiment

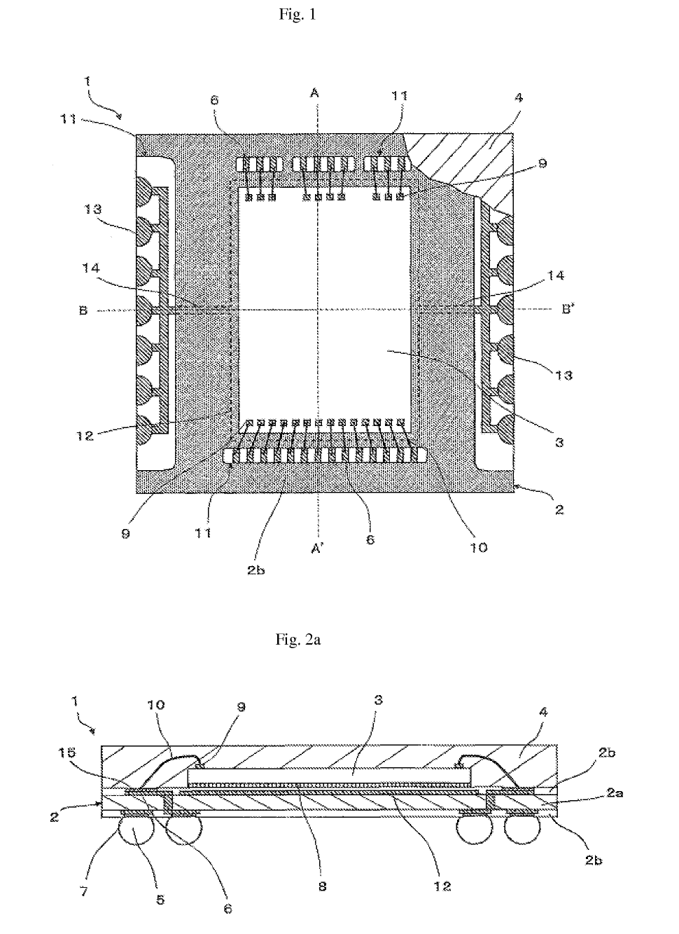

FIG. 1 is a plan view showing a semiconductor device according to a first mode of embodiment of the present invention.

As shown in FIG. 1, a semiconductor device 1 comprises: a wiring board 2 including an insulating substrate 2a on which a conductive pattern 12 is formed and heat-radiating vias 13 are formed passing through the insulating substrate from a first surface to a second surface thereof while also being exposed at the sides of the insulating substrate; and a semiconductor chip 3 which is mounted in a central region on a first surface of the wiring board 2. In addition, the semiconductor device 1 comprises a sealing material 4 which is formed on the first surface of the wiring board 2 in such a way as to cover the semiconductor chip 3. FIG. 1 shows the internal structure with part of the sealing material 4 removed.

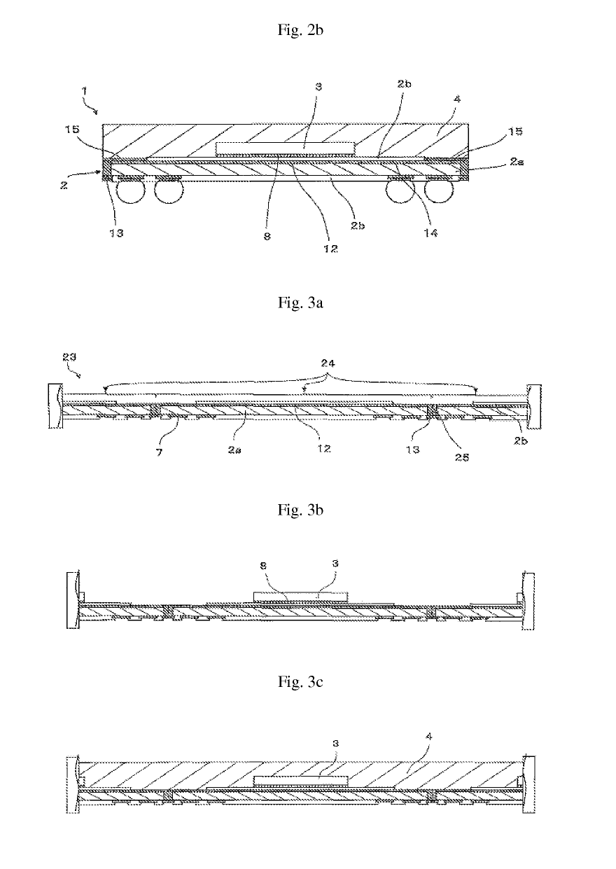

The wiring board 2 comprises the insulating substrate 2a such as a glass epoxy board, and predetermined wiring patterns (not depicted) are formed on the first and second surfaces of the insulating substrate 2a, these wiring patterns being covered by an insulating film 2b such as a solder resist film 2b. The wiring pattern on the first surface is formed at a position that does not overlap the conductive pattern 12 in a plane and is not connected to the conductive pattern 12. As shown in FIG. 1 and FIG. 2a, the insulating film 2b has openings 11 at positions opposite connection pads 6 (to be described later) and the heat-radiating vias 13. The plurality of connection pads 6 which are connected to the wiring pattern formed on the first surface of the wiring board 2 are exposed from the openings 11 in the insulating film 2b along a pair of sides opposite the mounted semiconductor chip 3. Furthermore, as shown in FIGS. 2a and 2b, a plurality of lands 7 are exposed from the openings 11 in the insulating film 2b which is formed on a second surface of the wiring board 2. The connection pads 6 and the lands 7 are formed from Cu or the like and are electrically connected by way of through-vias formed inside the wiring board 2. A plurality of solder balls 5 (metal balls) connected to the lands 7 are provided on the second surface of the wiring board 2, in two rows along each side of the wiring board 2 in a region excluding the central region of the second surface of the wiring board 2.

The semiconductor chip 3 is a memory chip for a dynamic random access memory (DRAM), for example, and it has the shape of a rectangular plate, as shown in FIG. 1. A plurality of electrode pads 9 are provided on a first surface of the semiconductor chip 3 along a pair of opposing sides, and a second surface (connecting surface) of the semiconductor chip 3 is connected by way of an adhesive member 8 to a central region of the wiring board 2, as shown in FIG. 2a and FIG. 2b. An insulating paste or a die-attached film (DAF) etc. may be used as the adhesive member 8, for example. As shown in FIG. 1 and FIG. 2a, the connection pads 6 and the electrode pads 9 are adjacent and are electrically connected by means of conductive wires 10.

Furthermore, as shown in FIG. 1 and FIGS. 2a and 2b, the conductive pattern 12 which is larger in size than the semiconductor chip 3 is formed on the first surface of the insulating substrate 2a of the wiring board 2. The semiconductor chip 3 is mounted directly over the conductive pattern 12. In addition, the heat-radiating vias 13 are disposed along a pair of opposing sides of the wiring board 2 which are parallel with the pair of sides of the semiconductor chip 3 on which the electrode pads 9 are not formed, and the heat-radiating vias 13 are exposed at the sides of the insulating substrate 2a. The heat-radiating vias 13 pass through the insulating substrate 2a from the first surface to the second surface thereof. The heat-radiating vias 13 are exposed at the openings 11 in the insulating film 2b, and a plating layer 15 is formed on the surface of the heat-radiating vias 13. However, if the heat-radiating vias 13 are exposed at the sides of the insulating substrate 2a they do not need to be exposed from the openings 11 in the insulating film 2b. The conductive pattern 12 and the heat-radiating vias 13 are connected by means of connection wires 14. The conductive pattern 12, heat-radiating vias 13 and connection wires 14 are formed from Cu or the like which has high thermal conductivity. The heat-radiating vias 13 and the through-vias 30 are the same size.

Heat generated by the semiconductor chip 3 is readily transmitted to the heat-radiating vias 13 through the conductive pattern 12 by virtue of the fact that the conductive pattern 12 provided directly below the semiconductor chip 3 is connected to the heat-radiating vias 13 in this way. The heat is then readily released from the exposed heat-radiating vias 13 to outside of the semiconductor device 1 by virtue of the fact that the heat-radiating vias 13 are exposed at the sides of the insulating substrate 2a. In this mode of embodiment, the surface contact area between the air and the heat-radiating vias 13 is increased at the sides of the insulating substrate 2a by virtue of the fact that the heat-radiating vias 13 are arranged passing through the insulating substrate 2a, and therefore there is a high heat-radiating effect. This means that the semiconductor chip 3 itself is unlikely to retain heat and the reliability of the semiconductor device 1 is improved. In addition, the plating layer 15 is formed on the surface of the heat-radiating vias 13 in the semiconductor device 1, and as a result it is possible to increase the surface area of the metal pattern exposed at the sides of the insulating substrate 2a proportionately with the plating layer 15.

In addition, there is no need to form additional heat-radiating solder balls etc. so the cost of manufacturing the semiconductor device 1 can be kept down.

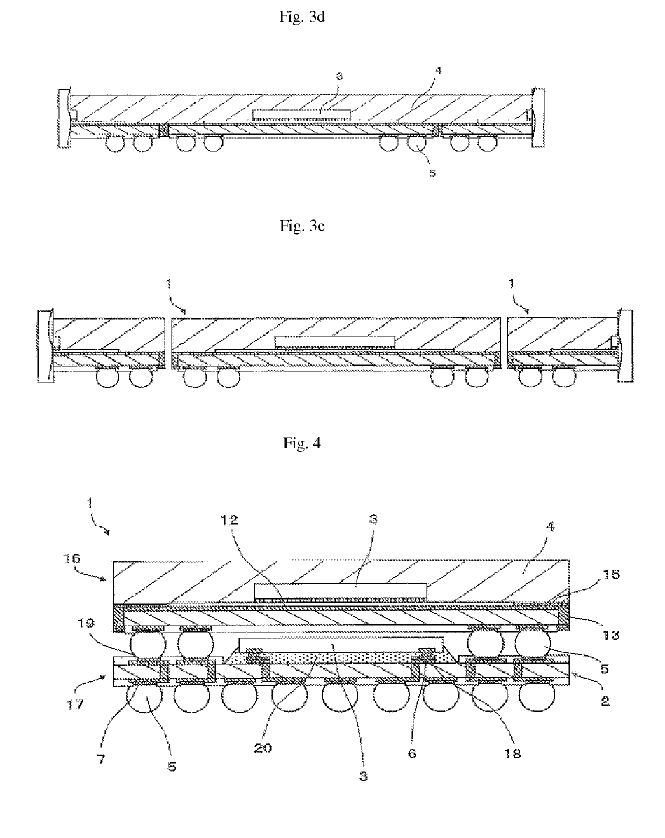

The steps in the manufacture of the semiconductor device 1 according to the first mode of embodiment of the present invention will be described below with the aid of FIG. 3a-3e.

As shown in FIG. 3a, a motherboard 23 comprising a plurality of product formation portions 24 (portions which will form wiring boards 2 after cutting) demarcated in the shape of a matrix by means of dicing lines 25 is first of all prepared. A plurality of connection pads 6 (see FIG. 1) and a conductive pattern 12 are formed on a first surface of the product formation portions 24 on the motherboard 23, and a plurality of lands 7 are formed on a second surface of the product formation portions 24. Furthermore, heat-radiating vias 13 are formed in portions including the dicing lines 25 in such a way as to pass through the motherboard 23 from the first surface to a second surface thereof. In addition, an insulating film 2b is provided on both surfaces of the motherboard 23, and the connection pads 6 (see FIG. 1), the conductive pattern 12, the heat-radiating vias 13 and the lands 7 are exposed from openings 11 in the insulating film 2b.

Next, as shown in FIG. 3b, an adhesive member 8 such as an insulating paste or a DAF is coated over the insulating film 2b in the central region of the first surface of the product formation portions 24, and a semiconductor chip 3 is mounted on the adhesive member 8 in such a way that the connecting surface of the semiconductor chip 3 is facing the first surface of the wiring board 2. The semiconductor chip 3 comprises a Si substrate having a DRAM memory circuit or the like formed on a first surface thereof, and a plurality of electrode pads 9 (see FIG. 1) are provided on the Si substrate. Furthermore, a passivation film (not depicted) for protecting the circuit is formed on the first surface of the semiconductor chip 3 in such a way that the surfaces of the electrode pads 9 are not covered.

After a semiconductor chip 3 has been mounted in each product formation portion 24, the electrode pads 9 of the mounted semiconductor chip 3 and the connection pads 6 of the motherboard 23 are connected by means of conductive wires 10 (see FIG. 1). The wires 10 comprise Au or Cu, for example. A wire bonding apparatus which is not depicted is used for the wire bonding to connect the electrode pads 9 and the connection pads 6 using the wires 10. Specifically, one end of the wire 10 which has been melted to form a ball shape is bonded to the electrode pad 9 of the semiconductor chip 3 by means of ultrasonic thermocompression bonding, after which the other end of the wire 10 is bonded to the connection pad 6 of the motherboard 23 by means of ultrasonic thermocompression bonding. The wire 10 is arranged in such a way as to describe a predetermined loop shape in order to avoid contact with the edge at the end of the semiconductor chip 3.

Following on from this, as shown in FIG. 3c, a sealing material 4 is formed on the first surface of the motherboard 23 in such a way as to cover the plurality of product formation portions 24 all together. Specifically, the sealing material 4 is formed using a molding apparatus such as a transfer mold apparatus having molding dies (not depicted) comprising an upper die and a lower die. A cavity having a size that covers the plurality of product formation portions 24 all together is formed in the upper die and a recess for arranging the motherboard 23 is formed in the lower die. The motherboard 23 in which the wires 10 are provided is set in the recess of the lower die, the peripheral edges of the motherboard 23 are clamped by the upper die and the lower die, and the motherboard 23 is arranged inside the cavity. After this, a heat-curable sealing resin such as an epoxy resin is charged in the cavity and heat-cured at a predetermined temperature (180° C., for example), whereby the sealing resin is cured and the sealing material 4 is formed on the first surface of the motherboard 23.

After the sealing material 4 has been formed on the first surface of the motherboard 23, the process moves to a ball mounting step in which solder balls 5 are formed on the second surface of the motherboard 23. Specifically, as shown in FIG. 3d, conductive solder balls 5 are bonded over the plurality of lands 7 disposed on each product formation portion 24 on the second surface of the motherboard 23. The solder balls 5 are suction-attached and held by means of a ball mount (not depicted) in which a plurality of suction-attachment holes are formed to match the arrangement of the lands 7, and the solder balls 5 are bonded all together to the lands 7 with flux interposed.

Finally, the areas between the product formation portions 24 are cut along the dicing lines 25 by means of a dicing apparatus which is not depicted in order to separate the product formation portions 24, and the semiconductor device 1 is completed as a result, as shown in FIG. 3e. Here, the dicing lines 25 are provided in such a way as to pass through the center of the heat-radiating vias 13, so the heat-radiating vias 13 are exposed at the sides of the semiconductor device 1 as a result of being cut and separated along the dicing lines 25.

FIG. 4 is a view in cross section showing a PoP semiconductor device having a structure in which an upper-stage package 16 is stacked on a lower-stage package 17 comprising a semiconductor chip 3, where the upper-stage package 16 is a semiconductor device having the structure described above.

The lower-stage package 17 comprises a wiring board 2 having a predetermined wiring pattern (not depicted) formed on a first surface thereof, and a semiconductor chip 3 which is mounted in a central region of the first surface of the wiring board 2, with an underfill material 20 interposed. Both surfaces of the wiring board 2 are covered by an insulating film 2b, and openings (not depicted) are provided in the insulating film 2b. Connection lands 19 which are connected to solder balls 5 of the upper-stage package 16, and connection pads 6 which are connected to the semiconductor chip 3 of the lower-stage package 17 are exposed from the openings on the first surface of the wiring board 2. A plurality of lands 7 are exposed from openings on a second surface of the wiring board 2, and solder balls 5 are connected to these lands 7.

The solder balls 5 on the second surface of the wiring board 2 of the upper-stage package 16, and the connection lands 19 on the first surface of the wiring board 2 of the lower-stage package 17 are connected, and a PoP semiconductor device 1 having two different semiconductor chips 3 is formed. Here, the solder balls 5 are not provided in the central region on the second surface of the wiring board 2 of the upper-stage package 16, so the semiconductor chip 3 mounted on the lower-stage package 17 does not come into contact with the solder balls 5 on the second surface of the wiring board 2 of the upper-stage package 16. That is to say, the solder balls 5 on the second surface of the wiring board 2 of the upper-stage package 16 come into contact with the wiring board 2 of the lower-stage package 17 without coming into contact with the semiconductor chip 3 of the lower-stage package 17.

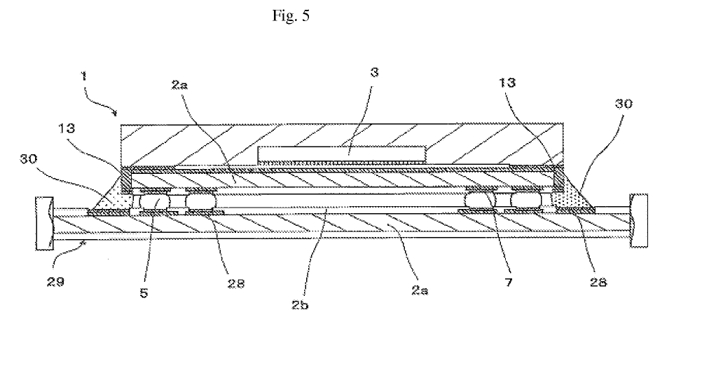

FIG. 5 is a view in cross section showing the situation when a semiconductor device having the structure described above is mounted on a mounting board of an electronic device.

A mounting board 29 such as a motherboard provided inside an electronic device comprises an insulating substrate 2a, and a predetermined wiring pattern (not depicted) is formed on a first surface and a second surface of the insulating substrate 2a. These wiring patterns are covered by an insulating film 2b such as a solder resist film. The insulating film 2b on the first surface comprises openings (not depicted), and a plurality of mounting board-side lands 28 which are connected to the wiring pattern formed on the first surface of the wiring board 2 are exposed from openings in the insulating film 2b. The mounting board-side lands 28 disposed directly below a mounted semiconductor device 1 are connected to lands of the mounted semiconductor device 1. When seen as a plane, the mounting board-side lands 28 disposed around the mounted semiconductor device 1 are connected to the heat-radiating vias 13 by way of solder 30. Heat transmitted to the heat-radiating vias 13 is therefore released from the heat-radiating vias 13 into the air while also being readily transmitted to the mounting board 29, by virtue of the fact that the mounting board-side lands 28 and the heat-radiating vias 13 are connected by way of the solder 30 in this way. In addition, the connection strength between the semiconductor device 1 and the mounting board 29 is enhanced by virtue of the fact that the mounting board-side lands 28 and the heat-radiating vias 13 are fixed by the solder 30, and it is possible to reduce the stress exerted on the solder balls 5 so the reliability of secondary mounting is improved.

As mentioned above, heat generated by the semiconductor chip 3 is released to outside of the semiconductor device 1 from the sides of the insulating substrate 2a through the conductive pattern 12 and the heat-radiating vias 13. In particular, the solder 30 is connected to the heat-radiating vias 13 which pass from the first surface to the second surface of the insulating substrate 2a and the surface contact area between the air and the solder 30 connected to the heat-radiating vias 13 is increased, so a large amount of heat is readily released from the heat-radiating vias 13 through the solder 30. In addition, heat is readily transmitted to the mounting board 29 through the heat-radiating vias 13 and the solder 30. It is therefore no longer necessary to provide heat-radiating solder balls in the central region of the second surface of the wiring board 2 in order to release heat to the mounting board. Accordingly, it is possible to make effective use of an arrangement in which the upper-stage package 16 of a PoP semiconductor device 1 formed by stacking the upper-stage package 16 and a lower-stage package 17 comprises a conductive pattern 12 and heat-radiating vias 13 which are provided in such a way as to be exposed at the sides of an insulating substrate 2a. This means that the heat of the semiconductor chip 3 of the upper-stage package 16 is readily released to outside of the semiconductor device 1 from the heat-radiating vias 13 which are exposed at the sides of the insulating substrate 2a, and the reliability of the PoP semiconductor device 1 is improved.

The description of this mode of embodiment relates to a case in which the connection pads 6 and the conductive pattern 12 are formed in the same layer interposed between the insulating substrate 2a and the insulating film 2b, but the connection pads 6 and the conductive pattern 12 may equally be formed in separate layers. Furthermore, the connection pads 6 and conductive pattern 12 may be formed from different materials.

The description of this mode of embodiment further relates to a case in which the heat-radiating vias 13 are the same size as the through-vias which connect the connection pads 6 and the lands 7, but the heat-radiating vias 13 may be larger than the through-vias which connect the connection pads 6 and the lands 7.

### Second Mode of Embodiment

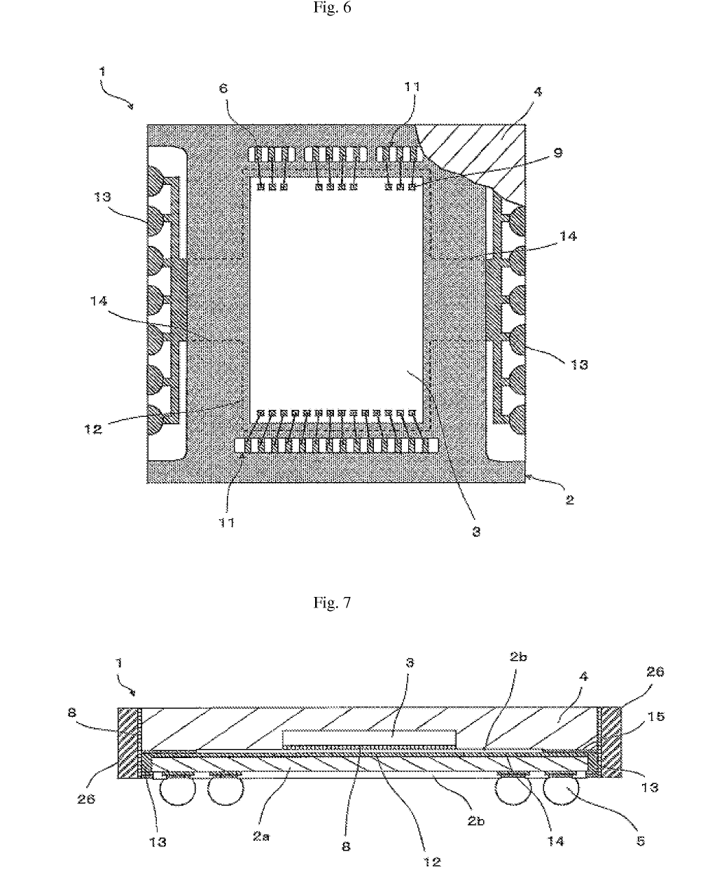

FIG. 6 is a plan view showing a semiconductor device according to a second mode of embodiment of the present invention.

The width of connection wires 14 for connecting a conductive pattern 12 and heat-radiating vias 13 in a semiconductor device 1 according to this mode of embodiment is greater than the width of the connection wires in the first mode of embodiment. The other constituent components of the semiconductor device 1 according to this mode of embodiment and the steps in the manufacture thereof are the same as in the first mode of embodiment and will therefore not be described again.

By increasing the width of the connection wires 14 in this way, the region of connection between the conductive pattern 12 and the heat-radiating vias 13 is increased and the amount of heat transmitted from the conductive pattern 12 to the heat-radiating vias 13 is increased. Heat generated by the semiconductor chip 3 is therefore readily released, through the conductive pattern 12, connection wires 14 and heat-radiating vias 13, to outside of the semiconductor device 1 from the heat-radiating vias 13 which are exposed at the sides of the insulating substrate 2a. As a result, the semiconductor chip 3 itself of the semiconductor device 1 is unlikely to retain heat and the reliability of the semiconductor device 1 is improved. The same advantages as in the first mode of embodiment are also achieved.

It should be noted that by providing a plurality of narrow connection wires 14, it is possible to produce an arrangement in which the total surface area in plan view is equal to that of the abovementioned wide connection wires 14.

### Third Mode of Embodiment

FIG. 7 is a view in cross section showing a semiconductor device according to a third mode of embodiment of the present invention.

A semiconductor device 1 according to this mode of embodiment comprises a heat-radiating plate 26 on the side surfaces of the semiconductor device 1 according to the first mode of embodiment in which the heat-radiating vias 13 are provided, with an adhesive member 8 interposed. After the semiconductor devices 1 have been cut and separated, the heat-radiating plate 26 is bonded over the adhesive member 8 which has been coated on the side surfaces of each semiconductor device 1. The heat-radiating plate 26 is formed from a material having excellent heat transfer properties in order to enhance the heat-radiating effect, and is adapted in such a way that the surface area thereof in contact with the air is increased. The other constituent components of the semiconductor device 1 according to this mode of embodiment and the steps in the manufacture thereof are the same as in the first mode of embodiment and will therefore not be described again.

By connecting the heat-radiating plate 26 to the heat-radiating vias 13 in this way, the surface area on the side surfaces of the semiconductor device 1 in contact with the air is increased. Heat generated by the semiconductor chip 3 and transmitted to the conductive pattern 12 is therefore readily released, through the connection wires 14, heat-radiating vias 13 and heat-radiating plate 26, to outside of the semiconductor device 1 from the heat-radiating plate 26 provided on the sides of the semiconductor device 1. As a result, the semiconductor chip 3 itself of the semiconductor device 1 is unlikely to retain heat and the reliability of the semiconductor device 1 is improved. The same advantages as in the first mode of embodiment are also achieved.

### Fourth Mode of Embodiment

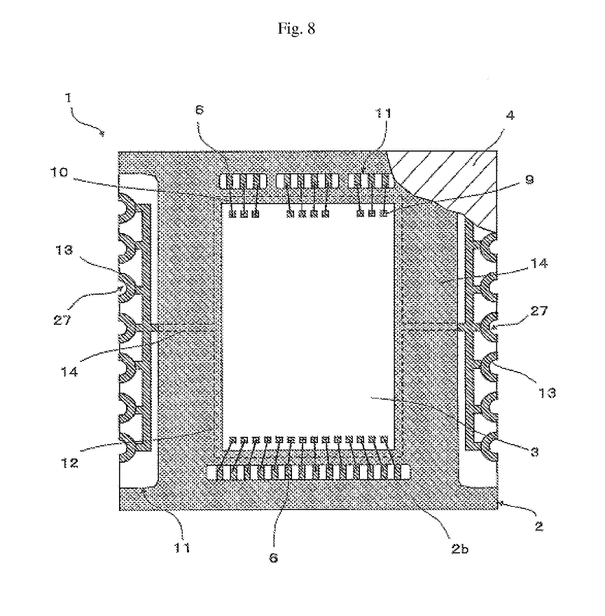

FIG. 8 is a view in cross section showing a semiconductor device according to a fourth mode of embodiment of the present invention.

A semiconductor device 1 according to this mode of embodiment has a structure in which a recess 27 is formed in the heat-radiating vias 13 which are exposed at the side surfaces of the insulating substrate 2a of the semiconductor device according to the first mode of embodiment. The recess 27 in the heat-radiating vias 13 may be formed when the semiconductor devices 1 are cut, or may be formed in an additional process after the semiconductor devices 1 have been separated. The recess 27 in the heat-radiating vias 13 is adapted in such a way as to increase the surface contact area with the air in order to enhance the heat-radiating effect. The other constituent components of the semiconductor device 1 according to this mode of embodiment and the steps in the manufacture thereof are the same as in the first mode of embodiment and will therefore not be described again.

By forming the recess 27 in the heat-radiating vias 13 in this way, the surface area of the heat-radiating vias 13 in contact with the air is increased. Heat generated by the semiconductor chip 3 and transmitted to the conductive pattern 12 is therefore readily released, through the connection wires 14 and the heat-radiating vias 13, to outside of the semiconductor device 1 from the heat-radiating vias 13 comprising the recess 27 which are exposed at the sides of the insulating substrate 2a. As a result, the semiconductor chip 3 itself of the semiconductor device 1 is unlikely to retain heat and the reliability of the semiconductor device 1 is improved. The same advantages as in the first mode of embodiment are also achieved.

### Fifth Mode of Embodiment

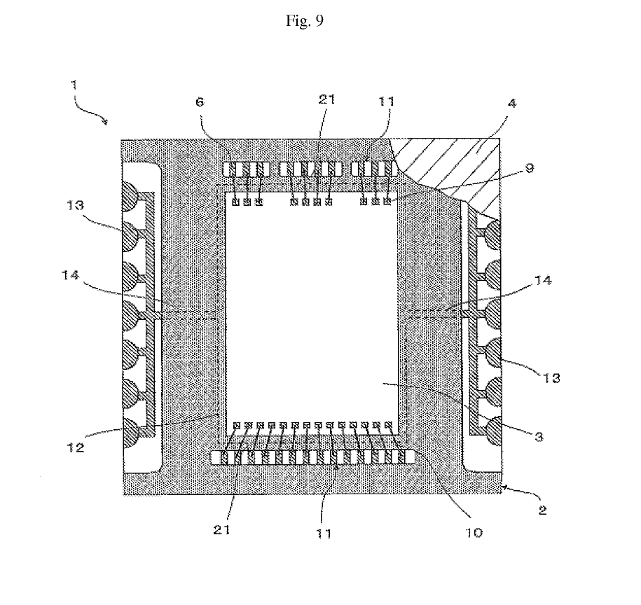

FIG. 9 is a plan view showing a semiconductor device according to a fifth mode of embodiment of the present invention.

A semiconductor device 1 according to this mode of embodiment comprises the constituent components of the first mode of embodiment, in addition to which the conductive pattern 12 and the connection pads 6 which are connected to a power source and GND are electrically connected by way of wires 21. The other constituent components of the semiconductor device 1 according to this mode of embodiment and the steps in the manufacture thereof are the same as in the first mode of embodiment and will therefore not be described again.

By electrically connecting the conductive pattern 12 to the connection pads 6 which are connected to the power source and GND by way of the wires 21 in this way, the conductive pattern 12 can serve as part of the wiring pattern on the wiring board 2. The manufacturing process is simplified by forming the conductive pattern 12 together with the wiring pattern on the wiring board 2. As a result, it is possible to keep down the cost of manufacturing the semiconductor device 1. The same advantages as in the first mode of embodiment are also achieved.

### Sixth Mode of Embodiment

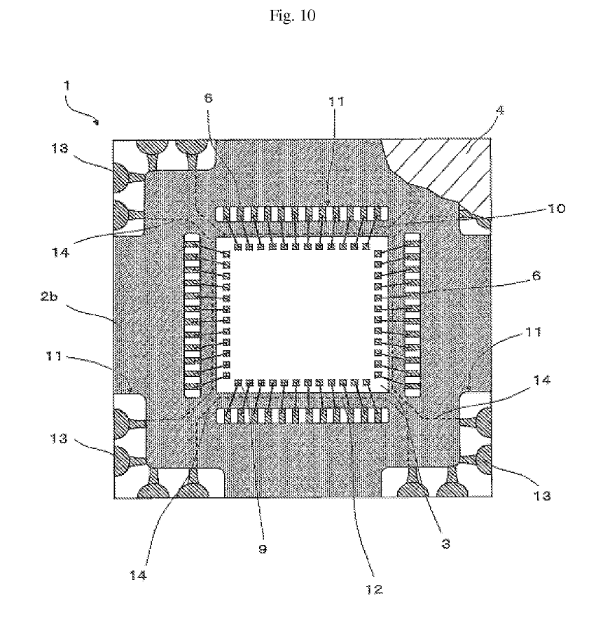

FIG. 10 is a plan view showing a semiconductor device according to a sixth mode of embodiment of the present invention.

A semiconductor device 1 according to this mode of embodiment comprises a wiring board 2, a semiconductor chip 3 mounted in the central region on a first surface of the wiring board 2, and a sealing material 4 formed on the first surface of the wiring board 2. FIG. 10 shows the internal structure with part of the sealing material 4 being removed. Both surfaces of the wiring board 2 are covered by an insulating film 2b having openings 11, and a plurality of connection pads 6 are exposed at the openings 11 in the insulating film 2b on the first surface of the wiring board 2 along the sides of the mounted semiconductor chip 3. The semiconductor chip 3 has a rectangular plate shape and a plurality of electrode pads 9 are provided on a first surface of the semiconductor chip 3 along the sides of the semiconductor chip 3. The connection pads 6 of the wiring board 2 and the electrode pads 9 of the semiconductor chip 3 are electrically connected by means of conductive wires 10. Furthermore, a conductive pattern 12 is formed between the insulating film 2b and a first surface of an insulating substrate 2a of the wiring board 2. The semiconductor chip 3 is formed directly above the conductive pattern 12. In addition, heat-radiating vias 13 are formed at the sides of the insulating substrate 2a in such a way as to lie either side of the four corners of the wiring board 2. The heat-radiating vias 13 are exposed from the openings 11 in the insulating film 2b, and a plating layer 15 is formed over the surface of the heat-radiating vias 13. The conductive pattern 12 and the heat-radiating vias 13 are connected by means of a plurality of connection wires 14.

The other steps in the manufacture of the semiconductor device 1 according to this mode of embodiment are the same as in the first mode of embodiment and will therefore not be described again.

By forming the heat-radiating vias 13 in such a way as to lie either side of the four corners of the wiring board 2 in this way, it is possible to make efficient use of the wires on the wiring board 2. It is therefore possible to form the connection pads 6 and the electrode pads 9 along the sides of the semiconductor chip 3, and a large number of electrode pads 9 are provided on the semiconductor chip 3. The same advantages as in the first mode of embodiment are also achieved.

The specific configuration of the semiconductor device according to the present invention has been described above on the basis of the modes of embodiment, but the present invention is not limited to these modes of embodiment and it goes without saying that various modifications may be made to the abovementioned modes of embodiment within a scope that does not depart from the essential point of the present invention. For example, the abovementioned modes of embodiment describe a semiconductor device in which one semiconductor chip is mounted on one wiring board, but the present invention may equally be applied to a multi-chip package (MCP) semiconductor device in which a plurality of semiconductor chips are placed in a row or stacked on one wiring board.

Furthermore, the abovementioned modes of embodiment describe a semiconductor device in which the electrode pads and connection pads are connected by wires, but the present invention may equally be applied to a flip-chip ball grid array (FC-BGA) semiconductor device in which the semiconductor chip is mounted with the electrode pads and connection pads being directly connected.

The present invention may further be applied to a chip-on-chip (CoC) semiconductor device in which through-electrodes are provided on semiconductor chips, and a chip stack formed by electrically connecting the semiconductor chips and the electrode pads thereof and stacking same is mounted on the semiconductor device.

1. A semiconductor device comprising:
a wiring board including an insulating substrate, a conductive pattern formed on a first surface of the insulating substrate, and heat-radiating vias which are connected to the conductive pattern and are provided in such a way as to be exposed at the sides of the insulating substrate while also passing through the insulating substrate from the first surface to a second surface thereof;
a semiconductor chip which is mounted on the wiring board in such a way as to lie over the conductive pattern; and
a sealing material which is formed on the insulating substrate in such a way as to cover the semiconductor chip.

2. The semiconductor device as claimed in claim 1, wherein the wiring board comprises an insulating film which is formed on the first surface of the insulating substrate in such a way as to cover the conductive pattern and to expose the heat-radiating vias.

3. The semiconductor device as claimed in claim 2, wherein the wiring board comprises a connection pad, and the insulating film has an opening at a position opposite the connection pad, and the conductive pattern is connected to the connection pad.

4. The semiconductor device as claimed in claim 1, comprising a plating layer provided on the surface of the heat-radiating vias and exposed on the first surface of the insulating substrate.

5. The semiconductor device as claimed in claim 1, wherein the conductive pattern and the heat-radiating vias are connected by means of a connection wire.

6. The semiconductor device as claimed in claim 1, comprising a heat-radiating plate connected to the heat-radiating vias.

7. The semiconductor device as claimed in claim 1, wherein a recess for enlarging the surface area in contact with the air is provided in the heat-radiating vias.

8. An electronic device comprising the semiconductor device as claimed in claim 1, and a mounting board having a plurality of lands formed on a first surface, wherein the heat-radiating vias of the semiconductor device and the lands of the mounting board are both fixed and electrically connected.

9. A semiconductor device comprising:
an upper-stage package having a wiring board including an insulating substrate, a conductive pattern formed on a first surface of the insulating substrate, and heat-radiating vias which are connected to the conductive pattern and are provided in such a way as to be exposed at the sides of the insulating substrate while also passing through the insulating substrate from the first surface to a second surface thereof;
a semiconductor chip which is mounted on the wiring board in such a way as to lie over the conductive pattern;
a sealing material which is formed on the wiring board in such a way as to cover the semiconductor chip;
metal balls which are provided on a second surface of the wiring board along the edges of the wiring board in such a way as to exclude the central region of the wiring board; and
a lower-stage package having a wiring board including an insulating substrate, a semiconductor chip mounted on a first surface of the wiring board, and metal balls mounted on a second surface of the wiring board, characterized in that the upper-stage package and the lower-stage package are stacked in such a way that the metal balls of the upper-stage package are not in contact with the semiconductor chip of the lower-stage package but are in contact with the wiring board of the lower-stage package.

10. The semiconductor device as claimed in claim 9, wherein connection lands are provided on the first surface of the wiring board of the lower-stage package, and the metal balls of the upper-stage package and the connection lands of the lower-stage package are connected.
